(19) United States
(12) Patent Application Publication
(10) Pub. No.: US 2017/0248828 A1
(43) Pub. Date: Aug. 31, 2017

(54) ARRAY SUBSTRATE, LIQUID CRYSTAL DISPLAY PANEL, AND LIQUID CRYSTAL DISPLAY DEVICE

(71) Applicant: Shenzhen China Star Optoelectronics Technology Co. Ltd., Shenzhen (CN)

(72) Inventor: Peng DU, Shenzhen (CN)

(73) Assignee: Shenzhen China Star Optoelectronics Technology Co. Ltd., Shenzhen (CN)

(21) Appl. No.: 14/897,664

(22) PCT Filed: Oct. 8, 2015
(86) PCT No.: PCT/CN2015/091472

§ 371 Date: Dec. 11, 2015

(30) Foreign Application Priority Data
Sep. 22, 2015 (CN) 201510605530.3

(51) Int. Cl. G02F 1/1362

(52) U.S. Cl. CPC G02F 1/136286; H01L 27/124

(57) ABSTRACT

An array substrate includes a plurality of scanning lines, and a plurality of data lines. A plurality of regions is formed with the cooperation of the scanning lines and the data lines. Each region is provided with one pixel. The data lines are formed by branch lines of a plurality of data signal lines, and one data signal line forms two branch lines so as to drive two pixels in a same row of the array substrate. The two pixels are spaced from each other by an odd number of pixels. With respect to pixels in two adjacent rows, pixels in one row are all coupled with a data line on a left side, and pixels in the other row are all coupled with a data line on a right side, so that dot inversion of signal of pixels is realized when column inversion occurs to signal of data lines.

### CROSS REFERENCE TO RELATED APPLICATION

The present application claims priority of Chinese patent application CN201510605530.3, entitled “Array Substrate, Liquid Crystal Display Panel, and Liquid Crystal Display Device” and filed on Sep. 22, 2015, the entirety of which is incorporated herein by reference.

### FIELD OF THE INVENTION

The present disclosure relates to the technical field of liquid crystal display, and particularly to an array substrate, a liquid crystal display panel, and a liquid crystal display device.

### BACKGROUND OF THE INVENTION

It is always an important task to reduce the production cost during the production of liquid crystal display panel. At present, the production cost of the liquid crystal display panel is generally reduced through Data Line Sharing (DLS) arrangement mode. According to the DLS arrangement mode, the number of scanning lines are doubled, while the number of data lines are halved, so that the number of source driving integrated circuits can be reduced, and the production cost of the display panel can be reduced accordingly.

At present, in the driving method of the liquid crystal display panel, dot inversion is a good one through which a best display effect can be realized. With respect to a liquid crystal display panel with the DLS arrangement mode, if traditional driving method is used, a polarity of a signal of a data line should be inverted once after each two pixels when an operational frequency is 60 Hz with a high definition. That is, the polarity of the signal of the data line should be inverted once after each 21.7 μs, and a frequency of the signal of the data line is 20 kHz. When the liquid crystal display panel with the DLS arrangement mode is driven by the aforesaid driving method, on the one hand, a power consumption of the data line is increased, and on the other hand, a charging time of the pixel is rather short. Meanwhile, the charging state of the pixel would be affected by RC delay effect resulted from the signal inversion of the data line, and a display effect of the panel would be adversely affected.

### SUMMARY OF THE INVENTION

In order to solve the aforesaid technical problem, the present disclosure provides an array substrate, a liquid crystal display panel, and a liquid crystal display device, whereby a power consumption of a data line can be reduced, and a charging state of a pixel can be improved.

According to a first aspect, the present disclosure provides an array substrate, which comprises:

a plurality of scanning lines; and

a plurality of data lines, wherein a plurality of regions can be formed with the cooperation of the scanning lines and the data lines, and each region is provided with one pixel;

wherein the data lines are formed by branch lines of a plurality of data signal lines, and one data signal line forms two branch lines so as to drive two pixels in a same row of the array substrate;

said two pixels are spaced from each other by an odd number of pixels; and

with respect to pixels in two adjacent rows, pixels in one row are all coupled with a data line on a left side, and pixels in the other row are all coupled with a data line on a right side, so that dot inversion of signal of pixels is realized when column inversion occurs to signal of data lines.

According to one embodiment of the present disclosure, pixels in one row of the array substrate are controlled by two scanning lines adjacent to the pixels in the row.

According to one embodiment of the present disclosure, pixels in one row which are driven by branch lines of same data signal line are controlled by different scanning lines.

According to one embodiment of the present disclosure, two pixels in one row which are driven by branch lines of same data signal line are spaced from each other by one pixel.

According to one embodiment of the present disclosure, pixels in two adjacent columns are seen as one column group, and two pixels in one row of one column group are controlled by same scanning line.

According to one embodiment of the present disclosure, with respect to pixels in two adjacent columns of one column group, pixels thereof in two adjacent rows are all controlled by scanning lines in odd-numbered rows or scanning lines in even-numbered rows.

According to one embodiment of the present disclosure, with respect to pixels in two adjacent columns of one column group, pixels thereof in one row of two adjacent rows are controlled by a scanning line in an odd-numbered row, and pixels thereof in the other row of two adjacent rows are controlled by a scanning line in an even-numbered row.

According to one embodiment of the present disclosure, the data lines are formed by branch lines of the data signal lines before entering into an active area.

According to a second aspect, the present disclosure provides a liquid crystal display panel which comprises the aforesaid array substrate.

According to a third aspect, the present disclosure provides a liquid crystal display device which comprises the aforesaid liquid crystal display panel.

According to the present disclosure, dot inversion of signal of pixel can be realized when column inversion occurs to signal of data lines, whereby power consumption of the display panel can be reduced, a charging state of the pixel can be improved, and a display quality of the panel can be improved.

Other features and advantages of the present disclosure will be further explained in the following description, and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE DRAWINGS

The accompanying drawings provide further understandings of the present disclosure and constitute one part of the description. The drawings are used for interpreting the present disclosure together with the embodiments, not for limiting the present disclosure. In the drawings:

FIG. 1 schematically shows a dot inversion diagram of a liquid crystal display panel with DLS arrangement mode in the prior art;

FIG. 2 shows waveform of signal of scanning line and data line of a liquid crystal display panel under traditional driving method;

FIG. 3 schematically shows an array substrate according to an embodiment of the present disclosure;

FIG. 4 shows waveform of signal of scanning line and data line of the array substrate as shown in FIG. 3;

FIG. 5 schematically shows pixels of a display panel in which the array substrate as shown in FIG. 3 and traditional pixel arrangement mode are used; and

FIG. 6 schematically shows pixels of a display panel in which the array substrate as shown in FIG. 3 and WRGB pixel arrangement mode are used.

### DETAILED DESCRIPTION OF THE EMBODIMENTS

The present disclosure will be illustrated in detail hereinafter in combination with the accompanying drawings to enable the purpose, technical solutions, and advantages of the present disclosure more clear.

In a display panel with Data Line Sharing (DLS) arrangement mode, the number of scanning lines are doubled, so that the number of data lines can be halved. Compared with a display panel with traditional arrangement mode, the total number of data lines of the display panel with DLS arrangement mode can be greatly reduced, so that the number of integrated circuits which drive the data lines can be reduced, and the production cost of the display panel can be reduced accordingly.

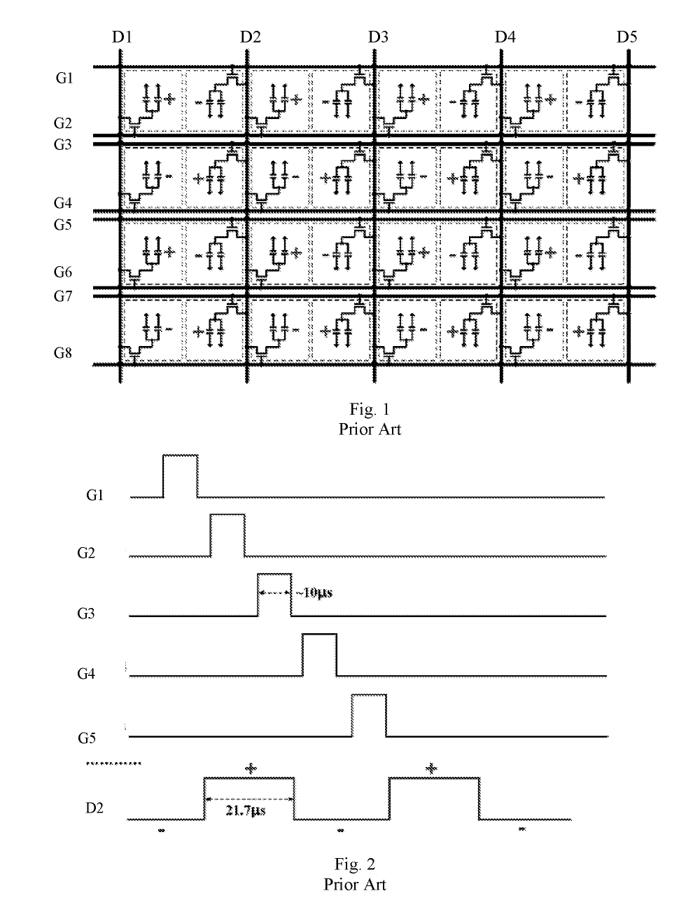

At present, the display panel is generally driven by an alternating current in which the polarity of the signal inverses regularly so as to avoid residual image when the display panel is driven by a direct current, and dot inversion is a good driving method through which a best display effect can be realized. FIG. 1 schematically shows a dot inversion diagram of a Thin Film Transistor Liquid Crystal Display (TFT-LCD) with DLS arrangement mode in the prior art.

As shown in FIGS. 1, G1 to G8 are scanning lines, and D1 to D5 are data signal lines. A part in a dotted line frame represents a pixel, in which “+” and “−” represent polarity of a driving voltage of a pixel. The polarity of the driving voltage of one pixel is opposite to the polarity of the driving voltage of adjacent pixels at an upper side, a lower side, a right side, and a left side respectively. That is, the panel is driven by dot inversion method.

The work principle of dot inversion will be illustrated below taking a second data line D2 as shown in FIG. 1 as an example. When G1 is turned on, D2 outputs a signal with negative polarity; when G2 and G3 are turned on, D2 outputs another signal with positive polarity; and when G4 and G5 are turned on, D2 outputs the signal with negative polarity. That is, when scanning lines numbered 4n+2 and 4n+3 (n=0, 1, 2 . . . ) are turned on, D2 outputs the signal with positive polarity; and when scanning lines numbered 4n and 4n+1 (n=0, 1, 2 . . . ) are turned on, D2 outputs the signal with negative polarity. The polarity of the signal of D2 should be inverted once when two pixels in a column direction are charged.

FIG. 2 shows waveform of signal of scanning line and data line of a liquid crystal display panel as shown in FIG. 1 under traditional driving method. The scanning lines G1, G2, G3, Gn, and Gn+1 are turned on in sequence, and the polarity of the signal of the data line should be inverted once after a time period during which two scanning lines are turned on. Taking the display panel with high definition as an example, the polarity of the signal of the data line D2 should be inverted once after each 21.7 μs. During one frame time period, the polarity of the signal of the data line D2 should be inverted for 768 times, and a frequency of the signal is about 20 kHz. As a result, the frequency of the signal of the data line is over high, and a power consumption of the panel would be increased. Moreover, the charging state of the pixel would be affected by RC delay effect of the data line, and a display effect of the panel would be adversely affected. The problem will become more serious when a resolution of the panel is improved.

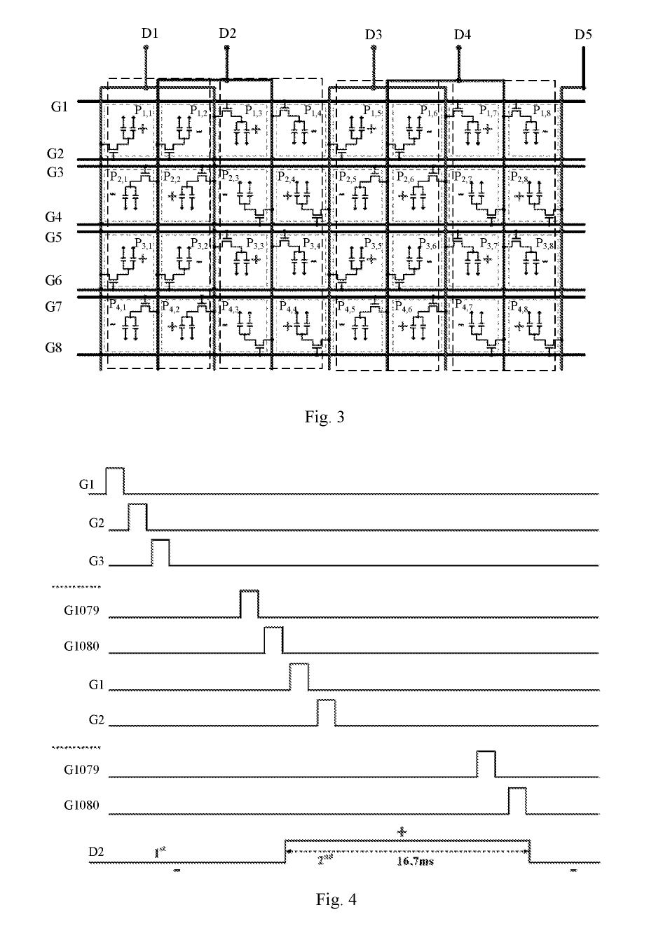

FIG. 3 schematically shows an array substrate according to an embodiment of the present disclosure. The present disclosure will be illustrate in detail hereinafter with reference to FIG. 3.

The array substrate comprises a plurality of scanning lines and a plurality of data lines. A plurality of regions can be formed with the cooperation of the scanning lines and the data lines, and each region is provided with one pixel. The data lines are formed by branch lines of a plurality of data signal lines. Here, the data signal lines refer to signal lines which are connected with a driving chip and which can output signal generated by the driving chip.

One data signal line forms two branch lines, which transmit a same driving signal. The two branch lines drive two pixels in a same row of the array substrate, and said two pixels are spaced from each other by an odd number of pixels. This is because, when dot inversion driving method is used, as shown in FIG. 3, two pixels in a same row which are spaced from each other by an odd number of pixels have a same polarity. Since two branch lines formed by same data signal line transmit the same driving signal, the dot inversion driving method can be realized only when two pixels in a same row which are spaced from each other by an odd number of pixels are driven by two branch lines formed by same data signal line.

As shown in FIG. 3, a fifth pixel P_{1,5} and a seventh pixel P_{1,7} in a first row are driven by a data signal line D3, and a sixth pixel P_{1,6} and a eighth pixel P_{1,8} in the first row are driven by a data signal line D4. Of course, a first pixel P_{1,1} and a fifth pixel P_{1,5} in the first row can also be driven by the data signal line D3, and a second pixel P_{1,2} and a sixth pixel P_{1,6} in the first row can also be driven by the data signal line D4, as long as it can be ensured that two pixels in the same row which are respectively driven by two branch lines formed by same data signal line have a same polarity.

In addition, since two pixels in a same row which are spaced from each other by an odd number of pixels are driven by two branch lines formed by same data signal line, two adjacent pixels in a same row or two pixels in a same row which are spaced from each other by an even number of pixels are respectively driven by branch lines formed by different data signal lines. As shown in FIG. 3, with respect to pixels in the first row, pixel P_{1,1} is driven by a data signal line D1, pixel P_{1,2} is driven by the data signal line D2, pixel P_{1,3} is driven by the data signal line D1, and pixel P_{1,4} is driven by the data signal line D2. On the same principle, pixels in the first row which are spaced from pixel P_{1,1} by an even number of pixels, such as pixel P_{1,4} and pixel P_{1,6} are driven by a data signal line other than the data signal line Dl.

In order to avoid complicated wiring arrangement in an active area, according to the present disclosure, the data lines are formed by branch lines of the data signal lines before entering into the active area, as shown in FIG. 3. In addition, one data signal line forms two branch lines so as to drive two pixels, and thus the number of data signal line can be halved. In this manner, the number of the driving chip can be reduced, and the production cost thereof can be reduced accordingly.

With respect to pixels in two adjacent rows of the array substrate, pixels in one row thereof are all coupled with a data line on a left side, and pixels in the other row thereof are all coupled with a data line on a right side. That is, with respect to pixels in a same column, two pixels in two adjacent rows are driven by different data lines, as shown in FIG. 3. With this arrangement, when the display panel is driven by the dot inversion driving method, the pixel with positive polarity and the pixel with negative polarity appear alternately in a same column. With respect to pixels in a same column and in two adjacent rows, one pixel has positive polarity, and the other pixel has negative polarity.

In this manner, during one image frame, the pixels in one column are respectively driven by the data lines arranged at the two sides thereof with opposite polarity. With this arrangement, in this image frame, the display of pixels with polarities as shown in FIG. 3 can be realized while the polarity of the signal of the data line does not change. When a next image frame is displayed, dot inversion of signal of pixel can be realized when column inversion occurs to signal of data lines. In this manner, the frequency of the signal of the data signal line can be reduced, and the power consumption of the panel can be reduced accordingly. Moreover, the influence of RC delay effect of the data line on the charging state of the pixel can be reduced, and a display quality of the display panel can be improved.

According to one embodiment of the present disclosure, pixels in one row of the array substrate are controlled by two scanning lines adjacent to the pixels in the row. Compared with traditional panel with DLS arrangement mode, the number of data signal lines and scanning lines of the array substrate disclosed herein are not increased, while the number of driving chips of date signal can be reduced. That is, the production cost can be reduced. Since two pixels in a same row which are spaced from each other by an odd number of pixels are driven by two branch lines formed by same data signal line, in order to realize the control of each pixel separately, according to one embodiment of the present disclosure, two pixels in a same row which are driven by two branch lines formed by same data signal line should be controlled by different scanning lines. For example, as shown in FIG. 3, in the first row, the fifth pixel P_{1,5} and the seventh pixel P_{1,7} are both driven by the data signal line D3, while the pixel P_{1,5} is controlled by a scanning line G2, and the pixel P_{1,7} is controlled by a scanning line G1.

As shown in FIG. 3, two pixels in one row which are driven by branch lines of same data signal line are spaced from each other by one pixel. That is, there is one pixel driven by branch lines of another data signal line between two pixels in one row which are driven by branch lines of same data signal line. With this arrangement, pixels in two adjacent columns are seen as one column group, and two pixels in one row of one column group are controlled by same scanning line. As shown in FIG. 3, pixels in a big dotted line frame are seen as one column group. That is, pixels in a first column and pixels in a second column are seen as one column group, and pixels in a third column and pixels in a fourth column are seen as one column group, and the like.

According to one embodiment of the present disclosure, with respect to pixels in two adjacent columns of one column group, pixels thereof in one row of two adjacent rows are controlled by a scanning line in an odd-numbered row, and pixels thereof in the other row of two adjacent rows are controlled by a scanning line in an even-numbered row. That is, with respect to pixels in two adjacent columns of one column group, two pixels thereof in an upper row of two adjacent rows are controlled by a scanning line in an odd-numbered row, and two pixels thereof in a lower row of two adjacent rows are controlled by a scanning line in an even-numbered row. Alternatively, with respect to pixels in two adjacent columns of one column group, two pixels thereof in an upper row of two adjacent rows are controlled by a scanning line in an even-numbered row, and two pixels thereof in a lower row of two adjacent rows are controlled by a scanning line in an odd-numbered row. As shown in FIG. 3, when pixels in the first column and pixels in the second column are seen as one column group, pixel P_{1,1} and pixel P_{1,2} in the first row are controlled by an even-numbered scanning line G2, pixel P_{2,1} and pixel P_{2,2} in a second row are controlled by an odd-numbered scanning line G3, and pixel P_{3,1} and pixel P_{3,2} in a third row are controlled by an even-numbered scanning line G6.

According to one embodiment of the present disclosure, with respect to pixels in two adjacent columns of one column group, pixels thereof in two adjacent rows are all controlled by scanning lines in odd-numbered rows or scanning lines in even-numbered rows. That is, with respect to pixels in two adjacent columns of one column group, two pixels thereof in an upper row of two adjacent rows are controlled by a scanning line in an odd-numbered row, and two pixels thereof in a lower row of two adjacent rows are also controlled by a scanning line in an odd-numbered row. Alternatively, with respect to pixels in two adjacent columns of one column group, two pixels thereof in an upper row of two adjacent rows are controlled by a scanning line in an even-numbered row, and two pixels thereof in a lower row of two adjacent rows are also controlled by a scanning line in an even-numbered row. As shown in FIG. 3, when pixels in the first column and pixels in the second column are seen as one column group, pixel P_{1,1} and pixel P_{1,2} in the first row are controlled by an even-numbered scanning line G2, pixel P_{2,1} and pixel P_{2,2} in the second row are controlled by an even-numbered scanning line G4, and pixel P_{3,1} and pixel P_{3,2} in the third row are controlled by an even-numbered scanning line G6.

FIG. 4 shows waveform of signal of scanning line and data line of the array substrate as shown in FIG. 3. It can be seen from FIG. 4 that, the array substrate as shown in FIG. 3 has a high definition and comprises 1080 scanning lines, and the scanning lines G1, G2, G3, . . . G1079, and G1080 are turned on in sequence. During a time period when one image frame is displayed on a display panel, the polarity of the signal of the data line does not change. When a next image frame is displayed, the polarity of the signal of the data line inverses once. The polarity of the signal of the data line does not change during the next image frame.

The pixels in the first row and the second row which are driven by a data signal line D3 and a data signal line D4 are taken as an example. The polarity of the present image is shown in FIG. 3. At this time, D3 outputs a positive driving signal, and D4 outputs a negative driving signal. Pixels P_{1,5}, P_{1,7}, P_{2,4} and P_{2,6} which are driven by the data signal line D3 all have positive polarity, while pixels P_{1,6}, P_{1,8}, P_{2,5} and P_{2,7} which are driven by the data signal line D4 all have negative polarity. During one image frame, pixels with positive polarity and pixels with negative polarity appear alternately both in horizontal direction and in vertical direction when the polarity of the data signal line D3 and the data signal line D4 does not change.

With the arrangement of the lines as shown in FIG. 3, when a next image frame is displayed, the polarity of the data signal line D3 and the data signal line D4 inverses.

Pixels P_{1,5}, P_{1,7}, P_{2,4} and P_{2,6} which are driven by the data signal line D3 all have negative polarity, while pixels P_{1,6}, P_{1,8}, P_{2,5} and P_{2,7} which are driven by the data signal line D4 all have positive polarity. During this image frame, the polarity of the data signal line D3 and the data signal line D4 does not change, and pixels with positive polarity and pixels with negative polarity appear alternately both in horizontal direction and in vertical direction. In this manner, dot inversion of signal of pixel in the active area can be realized when column inversion occurs to signal of data lines.

FIG. 5 schematically shows pixels of a display panel in which the array substrate as shown in FIG. 3 and traditional pixel arrangement mode are used. As shown in FIG. 5, R, G, and B represent pixels with red color, green color, and blue color respectively, and pixels in a same column of the panel have a same color. A red pixel, a green pixel, and a blue pixel in three adjacent columns can be seen as one pixel group, and the pixel group appears repeatedly in each row of the display panel. With respect to the pixels in a same column of the panel with a same color, pixels with positive polarity and pixels with negative polarity appear alternately. With respect to the pixels in a same row, red pixel, green pixel, and blue pixel are arranged in sequence, and two adjacent pixels have opposite polarities, as shown in FIG. 5. With the pixel design as shown in FIG. 5, pixels with three colors can be arranged in a regular manner, so that the display effect of the panel can be improved.

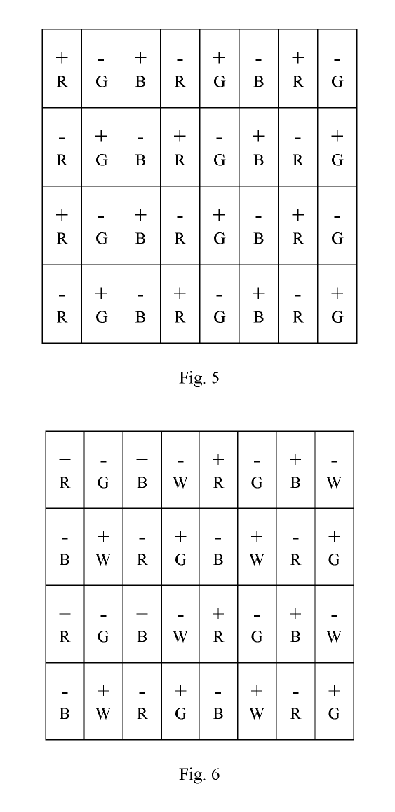

FIG. 6 schematically shows pixels of a display panel in which the array substrate as shown in FIG. 3 and WRGB pixel arrangement mode are used. As shown in FIG. 6, R, G, B, and W represent pixels with red color, green color, blue color, and white color respectively. With respect to the pixels in a same row, red pixel, green pixel, blue pixel, and white pixel are arranged in sequence, and two adjacent pixels have opposite polarities. With respect to the pixels in a same column, pixels with two different colors appear alternately, and two adjacent pixels have opposite polarities. Moreover, the pixels with a same color in two adjacent rows have opposite polarities, as shown in FIG. 6. With the pixel design as shown in FIG. 6, pixels with four colors can be arranged in a regular manner, so that the display effect of the panel can be improved.

According to a second aspect, the present disclosure provides a liquid crystal display panel, which comprises the aforesaid array substrate. When the array substrate is used, dot inversion of signal of pixel can be realized when column inversion occurs to signal of data lines. The polarity of the signal of the data line does not necessarily change during one image frame, and thus the power consumption of the display panel can be reduced. Moreover, a charging state of the pixel can be improved, and a display quality of the panel can be improved accordingly.

According to a third aspect, the present disclosure provides a liquid crystal display device, which comprises the aforesaid liquid crystal display panel. Dot inversion of signal of pixel can be realized when column inversion occurs to signal of data lines. The power consumption of the display panel can be reduced, the charging state of the pixel can be improved, and the display quality of the panel can be improved accordingly.

The above embodiments are described only for better understanding, rather than restricting, the present disclosure. Any person skilled in the art can make amendments to the implementing forms or details without departing from the spirit and scope of the present disclosure. The protection scope of the present disclosure shall be determined by the scope as defined in the claims.

1. An array substrate, comprising:
a plurality of scanning lines; and
a plurality of data lines, wherein a plurality of regions can be formed with the cooperation of the scanning lines and the data lines, and each region is provided with one pixel;
wherein the data lines are formed by branch lines of a plurality of data signal lines, and one data signal line forms two branch lines so as to drive two pixels in a same row of the array substrate;
said two pixels are spaced from each other by an odd number of pixels; and
with respect to pixels in two adjacent rows, pixels in one row are all coupled with a data line on a left side, and pixels in the other row are all coupled with a data line on a right side, so that dot inversion of signal of pixels is realized when column inversion occurs to signal of data lines.

2. The array substrate according to claim 1, wherein pixels in one row of the array substrate are controlled by two scanning lines adjacent to the pixels in the row.

3. The array substrate according to claim 2, wherein pixels in one row which are driven by branch lines of same data signal line are controlled by different scanning lines.

4. The array substrate according to claim 3, wherein two pixels in one row which are driven by branch lines of same data signal line are spaced from each other by one pixel.

5. The array substrate according to claim 4, wherein pixels in two adjacent columns are seen as one column group, and two pixels in one row of one column group are controlled by same scanning line.

6. The array substrate according to claim 5, wherein with respect to pixels in two adjacent columns of one column group, pixels thereof in two adjacent rows are all controlled by scanning lines in odd-numbered rows or scanning lines in even-numbered rows.

7. The array substrate according to claim 5, wherein with respect to pixels in two adjacent columns of one column group, pixels thereof in one row of two adjacent rows are controlled by a scanning line in an odd-numbered row, and pixels thereof in the other row of two adjacent rows are controlled by a scanning line in an even-numbered row.

8. The array substrate according to claim 1, wherein the data lines are formed by branch lines of the data signal lines before entering into an active area.

9. A liquid crystal display panel, comprising an array substrate, which comprises:
a plurality of scanning lines; and
a plurality of data lines, wherein a plurality of regions can be formed with the cooperation of the scanning lines and the data lines, and each region is provided with one pixel;
wherein the data lines are formed by branch lines of a plurality of data signal lines, and one data signal line forms two branch lines so as to drive two pixels in a same row of the array substrate;
said two pixels are spaced from each other by an odd number of pixels; and
with respect to pixels in two adjacent rows, pixels in one row are all coupled with a data line on a left side, and pixels in the other row are all coupled with a data line on a right side, so that dot inversion of signal of pixels is realized when column inversion occurs to signal of data lines.

10. The liquid crystal display panel according to claim 9, wherein pixels in one row of the array substrate are controlled by two scanning lines adjacent to the pixels in the row.

11. The liquid crystal display panel according to claim 10, wherein pixels in one row which are driven by branch lines of same data signal line are controlled by different scanning lines.

12. The liquid crystal display panel according to claim 11, wherein two pixels in one row which are driven by branch lines of same data signal line are spaced from each other by one pixel.

13. The liquid crystal display panel according to claim 12, wherein pixels in two adjacent columns are seen as one column group, and two pixels in one row of one column group are controlled by same scanning line.

14. The liquid crystal display panel according to claim 13, wherein with respect to pixels in two adjacent columns of one column group, pixels thereof in two adjacent rows are all controlled by scanning lines in odd-numbered rows or scanning lines in even-numbered rows.

15. The liquid crystal display panel according to claim 13, wherein with respect to pixels in two adjacent columns of one column group, pixels thereof in one row of two adjacent rows are controlled by a scanning line in an odd-numbered row, and pixels thereof in the other row of two adjacent rows are controlled by a scanning line in an even-numbered row.

16. The liquid crystal display panel according to claim 9, wherein the data lines are formed by branch lines of the data signal lines before entering into an active area.

17. A liquid crystal display device, comprising a liquid crystal display panel, which comprises an array substrate, and the array substrate comprises:
a plurality of scanning lines; and
a plurality of data lines, wherein a plurality of regions can be formed with the cooperation of the scanning lines and the data lines, and each region is provided with one pixel;
wherein the data lines are formed by branch lines of a plurality of data signal lines, and one data signal line forms two branch lines so as to drive two pixels in a same row of the array substrate;
said two pixels are spaced from each other by an odd number of pixels; and
with respect to pixels in two adjacent rows, pixels in one row are all coupled with a data line on a left side, and pixels in the other row are all coupled with a data line on a right side, so that dot inversion of signal of pixels is realized when column inversion occurs to signal of data lines.
